(19) United States
(12) Patent Application Publication
(10) Pub. No.: US 2024/0057274 A1
(43) Pub. Date: Feb. 15, 2024

(54) ELECTRONIC DEVICE

(71) Applicant: PEGATRON CORPORATION, Taipei City (TW)

(72) Inventors: Chien-Yi Wu, Taipei City (TW); Chao-Hsu Wu, Taipei City (TW); Hau Yuen Tan, Taipei City (TW); Chih-Wei Liao, Taipei City (TW); Shih-Keng Huang, Taipei City (TW); Wen-Hgin Chuang, Taipei City (TW); Chia-Hong Chen, Taipei City (TW); Lin-Hsu Chiang, Taipei City (TW); Cheng-Kuan Lin, Taipei City (TW); His-Yung Chen, Taipei City (TW)

(73) Assignee: PEGATRON CORPORATION, Taipei City (TW)

(21) Appl. No.: 18/327,860

(22) Filed: Jun. 1, 2023

(30) Foreign Application Priority Data
Aug. 15, 2022 (TW) 111130586

(51) Int. Cl. H05K 5/04; H05K 5/00; H01Q 5/307

(52) U.S. Cl. CPC H05K 5/04; H05K 5/0004; H01Q 5/307

(57) ABSTRACT

An electronic device including a metal back cover, a metal frame, a first radiator and a second radiator is provided. The metal frame includes a disconnected part and two connecting parts, the two connecting parts are located at two sides of the disconnected part, separated from the disconnected part and connected to the metal back cover. A U-shaped slot is formed between the disconnected part and the metal back cover, and between the disconnected part and the two connecting parts. The first radiator is located beside the disconnected part and includes a feeding end and a first connecting end away from the feeding end, and the first connecting end is connected to the disconnected part. The second radiator is located beside the disconnected part, and includes a ground end and a second connecting end opposite to each other. The ground end is connected to the metal back cover.

### CROSS-REFERENCE TO RELATED APPLICATION

This application claims the priority benefit of Taiwan application serial no. 111130586, filed on Aug. 15, 2022. The entirety of the above-mentioned patent application is hereby incorporated by reference herein and made a part of this specification.

### BACKGROUND

### Technical Field

The invention relates to an electronic device, and particularly relates to an electronic device with antenna.

### Description of Related Art

At present, how to configure an antenna in an electronic device with a metal casing is a research goal in the related field.

### SUMMARY

The invention is directed to an electronic device having a metal casing and an antenna.

The invention provides an electronic device including a metal back cover, a metal frame, a first radiator and a second radiator. The metal frame includes a disconnected part and two connecting parts, wherein the two connecting parts are located at two sides of the disconnected part, separated from the disconnected part and connected to the metal back cover. A U-shaped slot is formed between the disconnected part and the metal back cover, and between the disconnected part and the two connecting parts. The first radiator is located beside the disconnected part, and includes a feeding end and a first connecting end away from the feeding end, and the first connecting end is connected with the disconnected part. The second radiator is located beside the disconnected part and includes a ground end and a second connecting end. The ground end is connected to the metal back cover, and the second connecting end is connected with the disconnected part and away from the first connecting end. An antenna module is jointly formed by the feeding end of the first radiator, the first connecting end, the disconnected part, the second connecting end of the second radiator and the ground end.

In an embodiment of the invention, the antenna module excites at a first frequency band, a second frequency band and a third frequency band, and a length of the disconnected part is 0.5 times of a wavelength of the first frequency band. In an embodiment of the invention, the second radiator is located beside the first radiator, and a first coupling gap is formed between the first radiator and the second radiator.

In an embodiment of the invention, the first radiator includes a first section, a second section and a third section connected in sequence, the first section includes the feeding end, the second section is L-shaped and includes a first sub-section and a second sub-section, the first section and the third section are connected to the first sub-section, the first sub-section extends in an extending direction of the disconnected part and forms a second coupling gap with the disconnected part, and the second sub-section includes the first connecting end.

In an embodiment of the invention, the third section is located between the first section and the disconnected part, the antenna module excites at a fourth frequency band, and a length of the third section in the extending direction is 0.25 times of a wavelength of the fourth frequency band.

In an embodiment of the invention, a part of the first section and the third section are perpendicular to the metal back cover, and the second section is parallel to the metal back cover.

In an embodiment of the invention, the antenna module further includes a third radiator connected to one of the two connecting parts and close to the first connecting end, and the third radiator is configured to excite at a fifth frequency band.

In an embodiment of the invention, the first radiator includes a first section and a second section connected to each other, the first section includes the feeding end, the second section includes the first connecting end, a tail end, and a third connecting end located between the tail end and the first connecting end, the first section is connected to the third connecting end, the tail end is close to the second radiator, and the first section and a segment of the first radiator which is between the third connecting end and the tail end are configured to excite at a sixth frequency band.

In an embodiment of the invention, the disconnected part is L-shaped and includes a first disconnected section and a second disconnected section connected to each other, the first radiator and the second radiator are located beside the first disconnected section, the second connecting end is connected to the second disconnected section, a third coupling gap is formed between the second radiator and the first disconnected section, and the third coupling gap is configured to excite at a seventh frequency band.

In an embodiment of the invention, the antenna module is located at a corner of the electronic device.

Based on the above description, in the electronic device of the invention, a U-shaped slot is formed between the disconnected part of the metal frame and the metal back cover, and between the disconnected part and the two connecting parts. An antenna module is jointly formed from the feeding end of the first radiator, the first connecting end, the disconnected part, the second connecting end of the second radiator to the ground end.

### BRIEF DESCRIPTION OF THE DRAWINGS

The accompanying drawings are included to provide a further understanding of the invention and incorporated in and constitute a part of this specification. The drawings illustrate embodiments of the invention and, together with the description, serve to explain the principles of the invention.

FIG. 1 is a schematic top view of an electronic device according to an embodiment of the invention.

FIG. 2 is a partial schematic three-dimensional view of the electronic device of FIG. 1.

FIG. 3 is a partial schematic cross-sectional view of the electronic device of FIG. 1.

FIG. 4 is a plot diagram of frequency vs. VSWR of an antenna module of the electronic device of FIG. 1.

FIG. 5 is a plot diagram of frequency vs. antenna efficiency of an antenna module of the electronic device of FIG. 1.

FIG. 6 is a plot diagram of frequency vs. isolation between antenna modules of the electronic device of FIG. 1.

### DESCRIPTION OF THE EMBODIMENTS

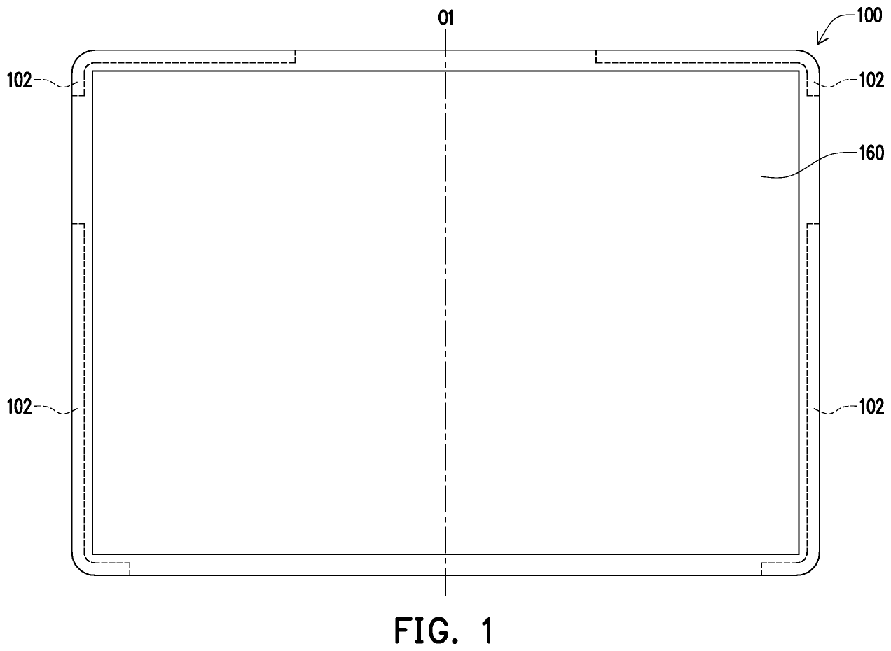

FIG. 1 is a schematic top view of an electronic device according to an embodiment of the invention. Referring to FIG. 1, in the embodiment, an electronic device 100 is, for example, a tablet computer, but the type of the electronic device 100 is not limited thereto. In the embodiment, the electronic device 100 includes four sets of antenna modules 102 disposed in a frame region outside a screen 160, and the four sets of antenna modules 102 are disposed at four corners of the electronic device 100.

In addition, in FIG. 1, the antenna modules 102 on the left and right sides are, for example, arranged symmetrically with respect to a central axis O1. In the two antenna modules 102 at the top of FIG. 1, a longer section of each antenna module 102 is located on a long side of the electronic device 100. In the two antenna modules 102 at the bottom of FIG. 1, the longer section of each antenna module 102 is located on a short side of the electronic device 100.

Certainly, in other embodiments, location configurations of these four sets of antenna modules 102 on the long side or the short side of the electronic device 100 are not limited thereto. For example, in the four antenna modules 102, the longer section of each antenna module 102 may also be located on the long side of the electronic device 100.

In addition, the number and the positions of the antenna modules 102 in the electronic device 100 are not limited thereto. In other embodiments, the electronic device 100 may also be configured with only two antenna modules 102 of the embodiment in collaboration with antennas of other bandwidths. Alternatively, in other embodiments, the electronic device 100 may also be configured with only one antenna module 102, and/or in collaboration with other antennas.

The antenna module 102 of the embodiment has broadband characteristics. The following is a description of a single antenna module 102.

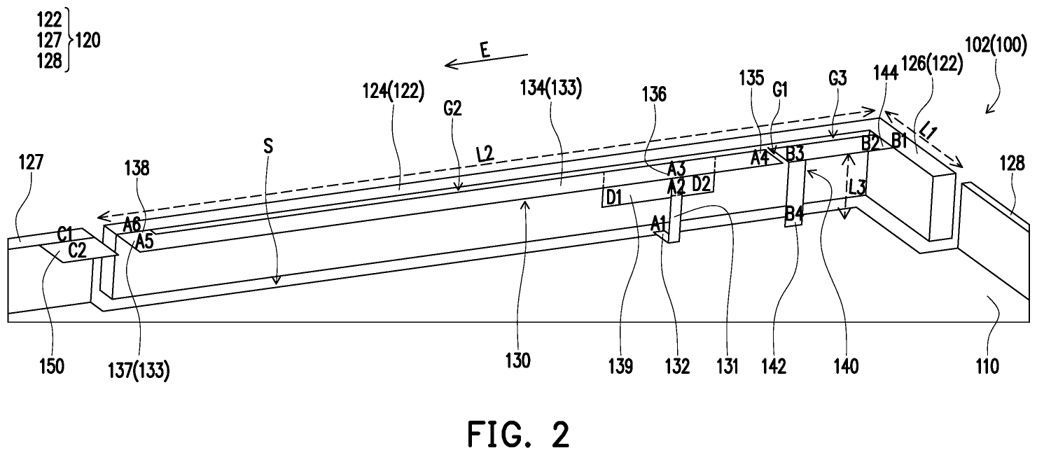

FIG. 2 is a partial schematic three-dimensional view of the electronic device of FIG. 1. It is noted that FIG. 2 only shows elements related to the antenna module 102. Referring to FIG. 2, the electronic device 100 of the embodiment includes a metal back cover 110, a metal frame 120, a first radiator 130 and a second radiator 140.

The metal frame 120 includes a disconnected part 122 and two connecting parts 127 and 128. The two connecting parts 127 and 128 are located on both sides of the disconnected part 122, separated from the disconnected part 122 and connected to the metal back cover 110. Specifically, the connecting parts 127 and 128 are the parts of the metal frame 120 near the disconnected part 122 and connected to the metal back cover 110.

A U-shaped slot S is formed between the disconnected part 122 and the metal back cover 110, and between the disconnected part 122 and the two connecting parts 127, 128. More specifically, as shown in FIG. 2, two vertical sections of the U-shaped slot S are located between the disconnected part 122 and the two connecting parts 127 and 128 on left and right sides. A horizontal section of the U-shaped slot S is located between the disconnected part 122 and the metal back cover 110. In the embodiment, a width of U-shaped slot S is, for example, 2 mm, but the invention is not limited thereto.

In the embodiment, the disconnected section 122 is L-shaped and includes a first disconnected section 124 and a second disconnected section 126 connected to each other. The first radiator 130 and the second radiator 140 are located beside the first disconnected section 124, and the first radiator 130 is connected to the first disconnected section 124, and the second radiator 140 is connected to the second disconnected section 126.

The first radiator 130 (positions A1-A6, D1, D2) is located beside the disconnected part 122 and located above the metal back cover 110. The first radiator 130 includes a feeding end 132 and a first connecting end 138 away from the feeding end 132. The first connecting end 138 is connected with the disconnected part 122.

The first radiator 130 comprises a first section 131 (positions A1 and A2), a second section 133 (positions A4, A3, A5 and A6) and a third section 139 (positions D1 and D2) connected in sequence to form multiple bends.

The first section 131 (positions A1 and A2) includes the feeding end 132. The second section 133 (positions A4, A3, A5, A6) is L-shaped and includes a first sub-section 134 (positions A4, A3, A5) and a second sub-section 137 (positions A5, A6).

The first section 131 (positions A1, A2) and the third section 139 (positions D1, D2) are connected to the first sub-section 134 (positions A4, A3, A5), and the second sub-section 137 includes the first connecting end 138. A part of the first section 131 and the third section 139 are perpendicular to the metal back cover 110, and the second section 133 is parallel to the metal back cover 110.

The second radiator 140 (positions B2 to B4) is located beside the disconnected part 122 and located above the metal back cover 110. The second radiator 140 includes a ground end 142 and a second connecting end 144. The ground end 142 is connected to the metal back cover 110, and the second connecting end 144 is connected with the second disconnected section 126 of the disconnected part 122 and is far away from the first connecting end 138.

In the embodiment, the antenna module 102 is jointly formed by the feeding end 132 of the first radiator 130, the first connecting end 138 (positions A1, A2, A4, A3, A5, A6), the disconnected part 122 (positions A6, B1), the second connecting end 144 of the second radiator 140, and the ground end 142 (positions B1, B2, B3, B4).

In the embodiment, the antenna module 102 excites at a first frequency band, a second frequency band and a third frequency band, and a length of the disconnected section 122 (length L1+L2) is 0.5 times of a wavelength of the first frequency band. In the embodiment, the length L1 is, for example, 11.5 mm, and the length L2 is, for example, 70 mm. The first frequency band is, for example, 610 MHz. The second frequency band is, for example, 930 MHz. The third frequency band is 2× frequency of the second frequency band, which is, for example, 1650 MHz.

In the embodiment, the length (length L1+L2) and width of the disconnected part 122 are related to a central frequency of the first frequency band. In addition, an inductance (for example, 1 nH-2 nH, not shown in the figure) connected to the ground end 142 and the metal back cover is related to the central frequencies of the second frequency band and the third frequency band.

In addition, a first coupling gap G1 is formed between the first radiator 130 and the second radiator 140. The first coupling gap G1 is configured to increase impedance matching of a low frequency band (i.e., the first frequency band combined with the second frequency band, for example, 617 MHz-960 MHz).

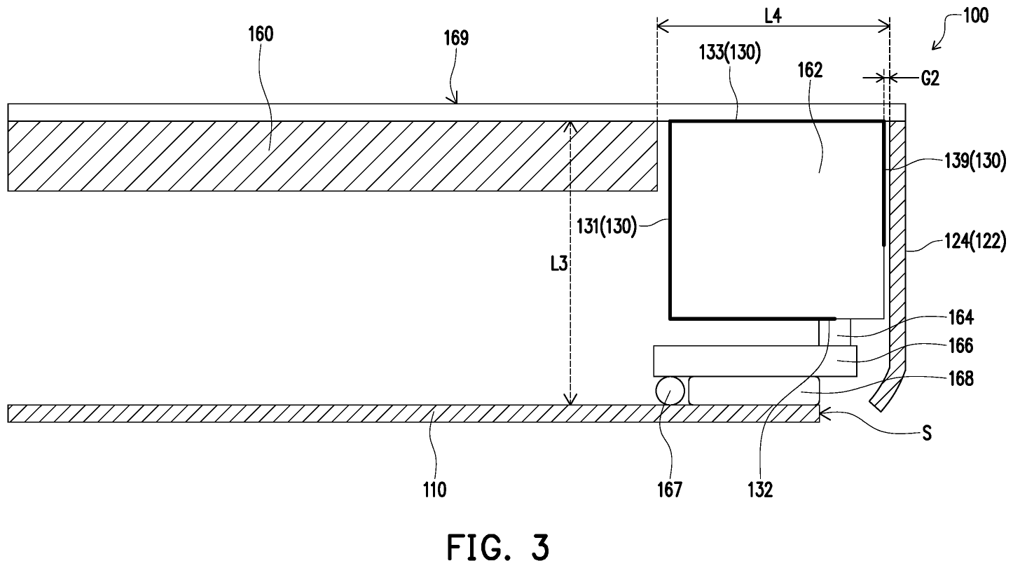

In addition, an RLC matching circuit (which may be configured on an antenna circuit board 166 in FIG. 3) connected in series to the feeding end 132 may improve the impedance matching of the first frequency band. For example, the RLC matching circuit is, for example, formed by first connecting the feeding end 132 with an inductor of 22 nH in parallel, then connecting with a capacitor of 2.2 pF in series, and then connecting with another inductor of 22 nH in parallel, but the RLC matching circuit is not limited thereto.

In the embodiment, the combination of the first frequency band and the second frequency band of the antenna module 102 may have ultra-wideband characteristics in the low frequency band (617 MHz-960 MHz). In other words, the antenna module 102 of the embodiment may support ultra-wideband in the low-frequency band (617 MHz-960 MHz) without adding a switching circuit in a limited space.

In addition, the first sub-section 134 (positions A5, A3, A4) extends in an extending direction E of the disconnected part 122 and forms a second coupling gap G2 with the first disconnected section 124 of the disconnected part 122.

The third section 139 (positions D1, D2) is located between the first section 131 and the first disconnected section 124 of the disconnected part 122, and the antenna module 102 excites at a fourth frequency band. The fourth frequency band is, for example, 2350 MHz, and a length of the third section 139 in the extending direction is 0.25 times of a wavelength of the fourth frequency band.

The antenna module 102 further includes a third radiator 150 (positions C1 and C2), which is connected to one of the two connecting parts 127 and 128, and is close to the first connecting end 138. The third radiator 150 is configured to excite at a fifth frequency band. The fifth frequency band is, for example, 2950 MHz. A width of the third radiator 150 (positions C1 and C2) is about 3 mm and a length of the third radiator 150 (positions C1 and C2) is about 5 mm, but the invention is not limited thereto.

In the embodiment, the second coupling gap G2, the third section 139 (positions D1, D2) and the third radiator 150 may jointly increase the impedance matching of the middle and high frequency bands (i.e., the fourth frequency band combines with the fifth frequency band, such as 1710 MHz-2690 MHz).

In addition to the first connecting end 138, the second section 133 of the first radiator 130 further includes a tail end 135 and a third connecting end 136 located between the tail end 135 and the first connecting end 138. The first section 131 is connected to the third connecting end 136, and the tail end 135 is close to the second radiator 140.

The first section 131 (positions A1, A2) and a segment (positions A3, A4) of the first radiator 130 which is between the third connecting end 136 and the tail end 135 are configured to excite at a sixth frequency band. The sixth frequency band is, for example, 3650 MHz (a main frequency of an ultra-high band UHB), and a path of the positions A1, A2, A3, and A4 is 0.25 times of a wavelength of the sixth frequency band. In addition, a length and width of the segment of the positions A3 and A4 may determine the central frequency of the sixth frequency band.

In addition, a third coupling gap G3 is formed between the second radiator 140 and the first disconnected section 124, and the third coupling gap G3 is configured to excite at a seventh frequency band. The seventh frequency band is, for example, 4400 MHz. The third coupling gap G3 is used to increase the impedance matching of the ultra-high band (i.e., the sixth frequency band combined with the seventh frequency band, such as 3300 MHz-5000 MHz).

FIG. 3 is a partial schematic cross-sectional view of the electronic device of FIG. 1. It should be noted that FIG. 3 is only a schematic illustration of the relative positions of these elements, and the proportions of these elements is not limited thereto. Referring to FIG. 3, in the embodiment, the first radiator 130, the second radiator 140 (FIG. 2) and the third radiator 150 (FIG. 2) are disposed on a bracket 162.

FIG. 3 is a schematic cross-sectional view of the first radiator 130. It may be seen from FIG. 3 that the first section 131 of the first radiator 130 extends from a lower surface of the bracket 162 to a lateral surface (a left surface of FIG. 3), the second section 133 is on an upper surface of the bracket 162, and the third section 139 is on another lateral surface (a right surface of FIG. 3) of the bracket 162. A distance L3 between the second section 133 and the metal back cover 110 is, for example, 6.3 mm.

The first radiator 130 is located beside the screen 160 and is not blocked by the screen 160. A glass cover 169 is, for example, arranged above the first radiator 130. The feeding end 132 of the first radiator 130 is connected to the antenna circuit board 166 through an elastic piece 164 and is connected with the RLC matching circuit (not shown) in series, and a ground plane of the antenna circuit board 166 is connected with the metal back cover 110 through a conductive foam 168. A positive end of a coaxial transmission line 167 is connected to the feeding end 132 through the antenna circuit board 166, and a negative end of the coaxial transmission line 167 is connected to the metal back cover 110.

The antenna module 102 of the embodiment is disposed in the frame region, and a width L4 of the frame region is 7.5 mm. Through the above design, the antenna module 102 may support a wide frequency band of a low frequency (617-960 MHz), a medium-high frequency (1710-2690 MHz) and ultra-high frequency n77-n79 (3300-5000 MHz) of 5G NR Sub-6G without an additional switching circuit and with the width L4 of only 7.5 mm for the frame region.

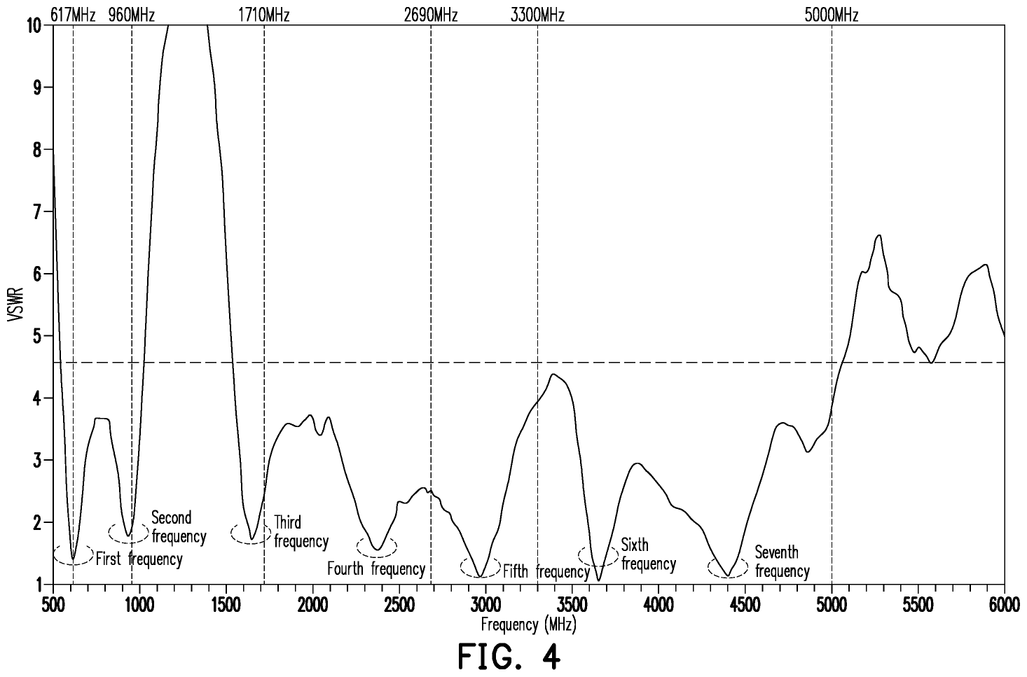

FIG. 4 is a plot diagram of frequency vs. VSWR of an antenna module of the electronic device of FIG. 1. Referring to FIG. 4, the VSWR of the antenna module 102 of the embodiment may be below 4.5 in the low frequency band 617 MHz-960 MHz, the medium-high frequency band 1710 MHz-2690 MHz and 3300 MHz-5000 MHz of the ultra-high frequency band n77-n79, and therefore achieves good performance. Therefore, the antenna module 102 of the embodiment has a broadband and multi-band capability.

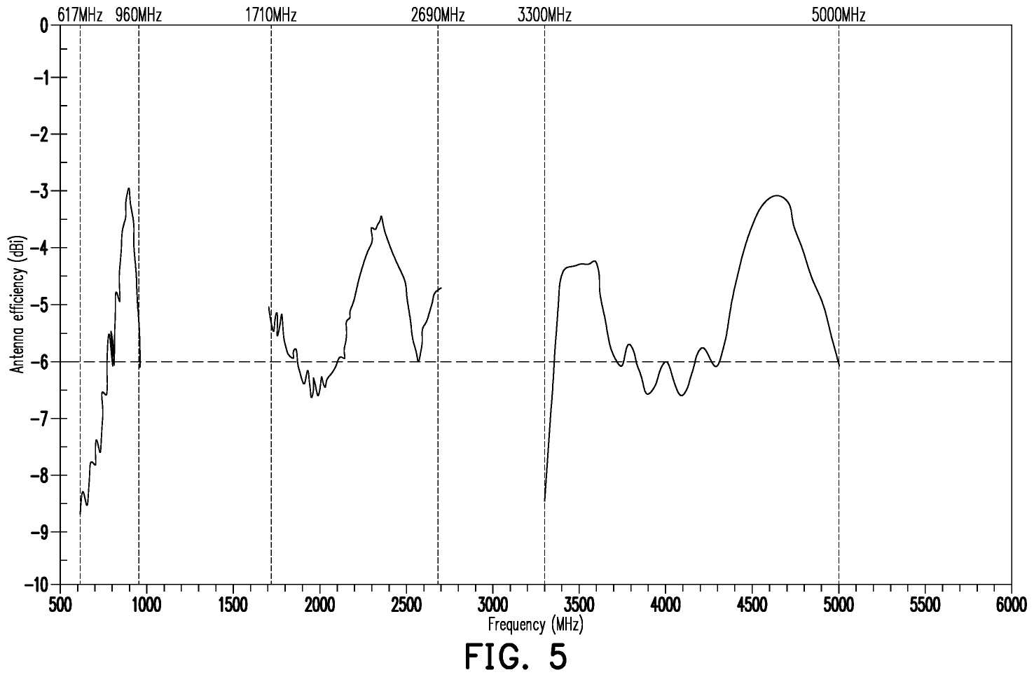

FIG. 5 is a plot diagram of frequency vs. antenna efficiency of an antenna module of the electronic device of FIG. 1. Referring to FIG. 5, the antenna module 102 of the embodiment has antenna efficiency of −3 dBi˜−8.7 dBi in the low frequency band 617 MHz-960 MHz and average antenna efficiency of −5.5 dBi in the medium-high frequency band 1710 MHz-2690 MHz and the ultra-high frequency band 3300 MHz-5000 MHz, and therefore achieves a good performance.

Referring back to FIG. 1, in the embodiment, two adjacent antenna modules 102 are separated by a partial metal frame 120. In other words, the partial metal frame 120 serves as an isolation element between the two antenna modules 102.

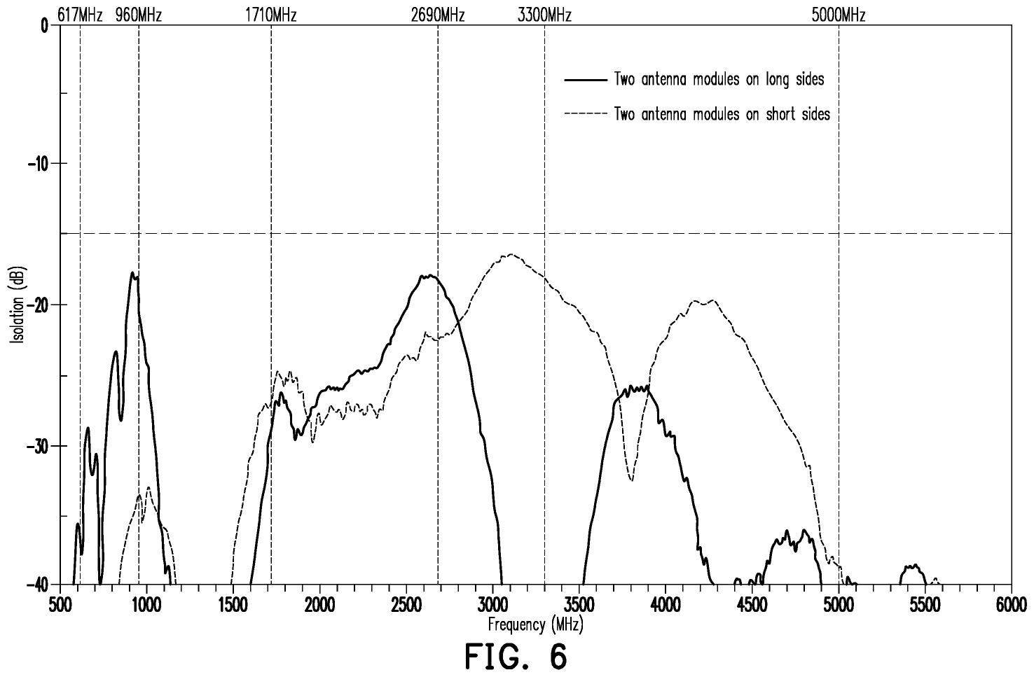

FIG. 6 is a plot diagram of frequency vs isolation between the antenna modules of the electronic device of FIG. 1. Referring to FIG. 6, regardless of the two antenna modules 102 disposed on the top (i.e., the two antenna modules 102 on the long side), or the two antenna modules 102 disposed on the right and left in FIG. 1 (i.e., the two antenna modules 102 on the short sides), an isolation performance thereof is at least above 15 dB.

In summary, in the electronic device of the invention, a U-shaped slot is formed between the disconnected part of the metal frame and the metal back cover, and between the disconnected part and the two connecting parts. An antenna module is jointly formed by the feeding end of the first radiator, the first connecting end, the disconnected part, and the second connecting end of the second radiator to the ground end, which has a broadband and multi-band capability.

What is claimed is:

1. An electronic device, comprising:
a metal back cover;
a metal frame, comprising a disconnected part and two connecting parts, wherein the two connecting parts are located at two sides of the disconnected part, separated from the disconnected part and connected to the metal back cover, and a U-shaped slot is formed between the disconnected part and the metal back cover, and between the disconnected part and the two connecting parts;
a first radiator, located beside the disconnected part and comprising a feeding end and a first connecting end away from the feeding end, wherein the first connecting end is connected with the disconnected part; and
a second radiator, located beside the disconnected part and comprising a ground end and a second connecting end, wherein the ground end is connected to the metal back cover, and the second connecting end is connected with the disconnected part and away from the first connecting end,
wherein, an antenna module is jointly formed by the feeding end of the first radiator, the first connecting end, the disconnected part, the second connecting end of the second radiator and the ground end.

2. The electronic device as claimed in claim 1, wherein the antenna module excites at a first frequency band, a second frequency band and a third frequency band, and a length of the disconnected part is 0.5 times of a wavelength of the first frequency band.

3. The electronic device as claimed in claim 1, wherein the second radiator is located beside the first radiator, and a first coupling gap is formed between the first radiator and the second radiator.

4. The electronic device as claimed in claim 1, wherein the first radiator comprises a first section, a second section and a third section connected in sequence, the first section comprises the feeding end, the second section is L-shaped and comprises a first sub-section and a second sub-section, the first section and the third section are connected to the first sub-section, the first sub-section extends in an extending direction of the disconnected part and forms a second coupling gap with the disconnected part, and the second sub-section comprises the first connecting end.

5. The electronic device as claimed in claim 4, wherein the third section is located between the first section and the disconnected part, the antenna module excites at a fourth frequency band, and a length of the third section along the extending direction is 0.25 times of a wavelength of the fourth frequency band.

6. The electronic device as claimed in claim 4, wherein a part of the first section and the third section are perpendicular to the metal back cover, and the second section is parallel to the metal back cover.

7. The electronic device as claimed in claim 1, wherein the antenna module further comprises a third radiator connected to one of the two connecting parts and close to the first connecting end, and the third radiator is configured to excite at a fifth frequency band.

8. The electronic device as claimed in claim 1, wherein the first radiator comprises a first section and a second section connected to each other, the first section comprises the feeding end, the second section comprises the first connecting end, a tail end, and a third connecting end located between the tail end and the first connecting end, the first section is connected to the third connecting end, the tail end is close to the second radiator, and the first section and a segment of the first radiator which is between the third connecting end and the tail end are configured to excite at a sixth frequency band.

9. The electronic device as claimed in claim 1, wherein the disconnected part is L-shaped and comprises a first disconnected section and a second disconnected section connected to each other, the first radiator and the second radiator are located beside the first disconnected section, the second connecting end is connected to the second disconnected section, a third coupling gap is formed between the second radiator and the first disconnected section, and the third coupling gap is configured to excite at a seventh frequency band.

10. The electronic device as claimed in claim 1, wherein the antenna module is located at a corner of the electronic device.
